(19) United States
(12) Patent Application Publication
(10) Pub. No.: US 2024/0088208 A1
(43) Pub. Date: Mar. 14, 2024

(54) SEMICONDUCTOR DEVICE STRUCTURE WITH METAL OXIDE LAYER AND METHOD FOR FORMING THE SAME

(71) Applicant: Taiwan Semiconductor Manufacturing Company, Ltd., Hsinchu (TW)

(72) Inventors: Tzu-Ting LIU, Taoyuan City (TW); Hsiang-Ku SHEN, Hsinchu City (TW); Wen-Tzu CHEN, Taoyuan city (TW); Man-Yun WU, Hsinchu (TW); Wen-Ling CHANG, Miaoli County (TW); Dian-Hau CHEN, Hsinchu (TW)

(21) Appl. No.: 18/152,950

(22) Filed: Jan. 11, 2023

Related U.S. Application Data
(60) Provisional application No. 63/375,255, filed on Sep. 12, 2022.

(51) Int. Cl. H01L 23/528; H01L 21/768

(52) U.S. Cl. CPC H01L 28/87; H01L 21/76898; H01L 23/5283; H01L 28/91

(57) ABSTRACT

A method for forming a semiconductor device structure is provided. The method includes forming an interconnect structure over a substrate. The method includes forming a first conductive pad and a mask layer over the interconnect structure. The mask layer covers a top surface of the first conductive pad. The method includes forming a metal oxide layer over a sidewall of the first conductive pad. The method includes forming a second conductive pad over the first conductive pad and passing through the mask layer. The first conductive pad and the second conductive pad are made of different materials.

### PRIORITY CLAIM AND CROSS-REFERENCE

This application claims the benefit of U.S. Provisional Application No. 63/375,255, filed on Sep. 12, 2022, and entitled “SEMICONDUCTOR DEVICE STRUCTURE WITH METAL OXIDE LAYER AND METHOD FOR FORMING THE SAME”, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1M are cross-sectional views of various stages of a process for forming a semiconductor device structure, in accordance with some embodiments.

FIG. 2 is a cross-sectional view of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

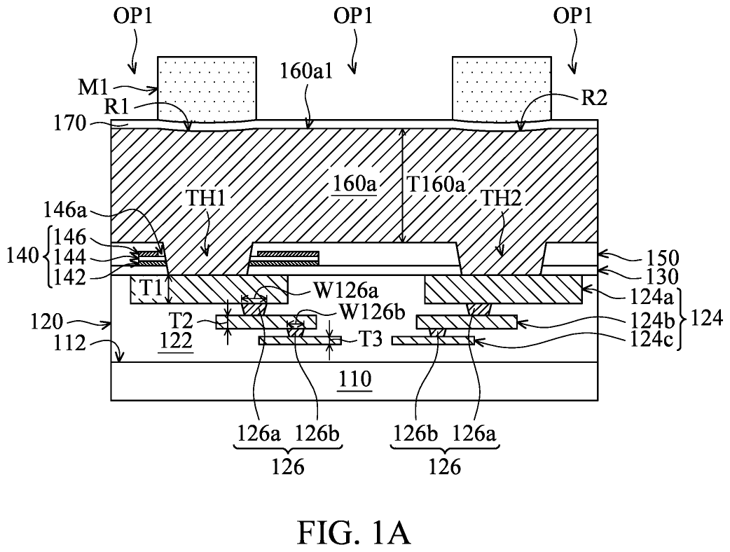

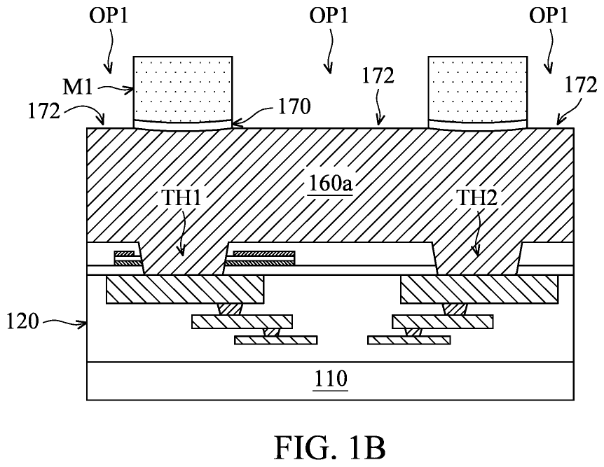

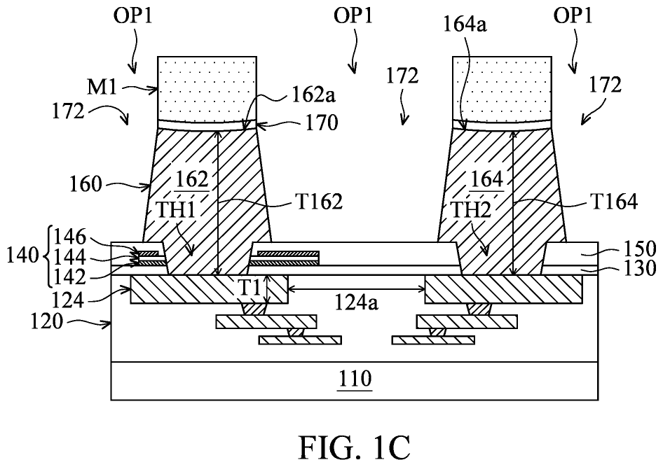

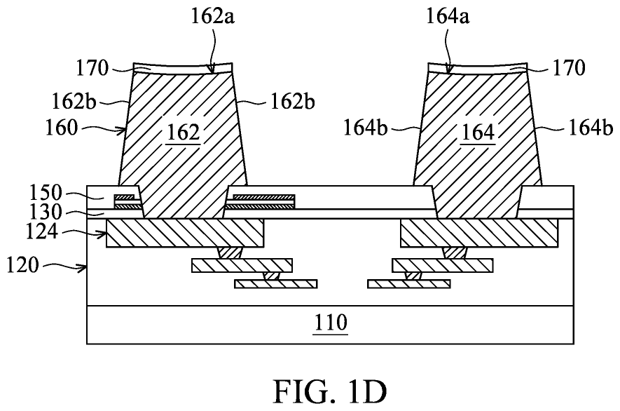

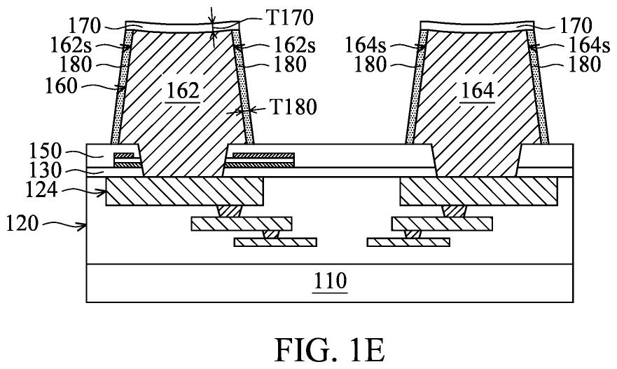

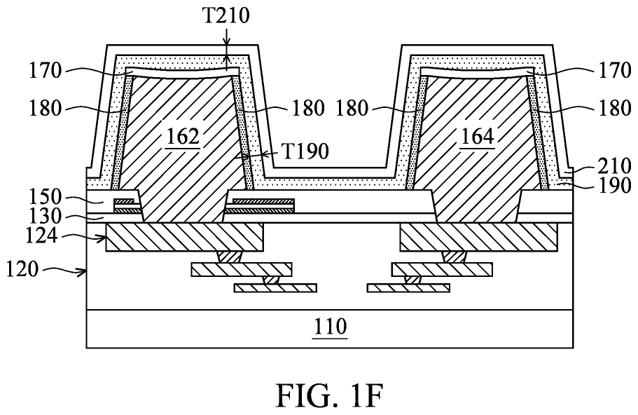

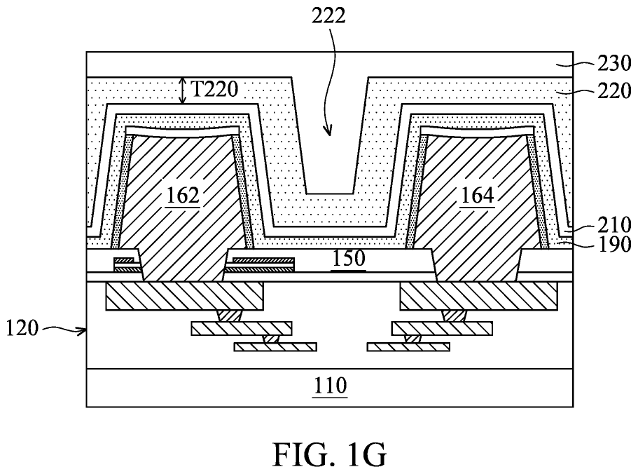

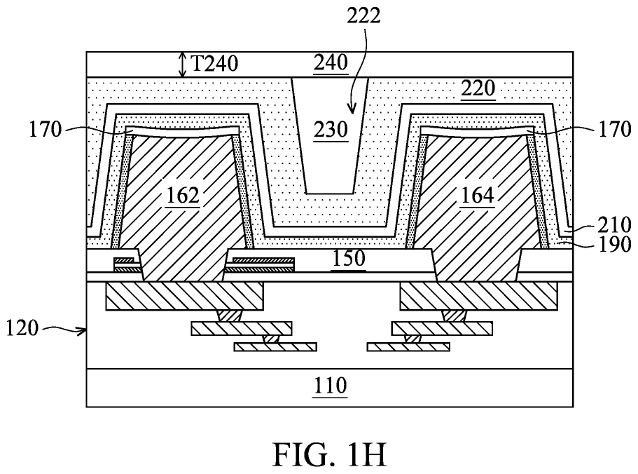

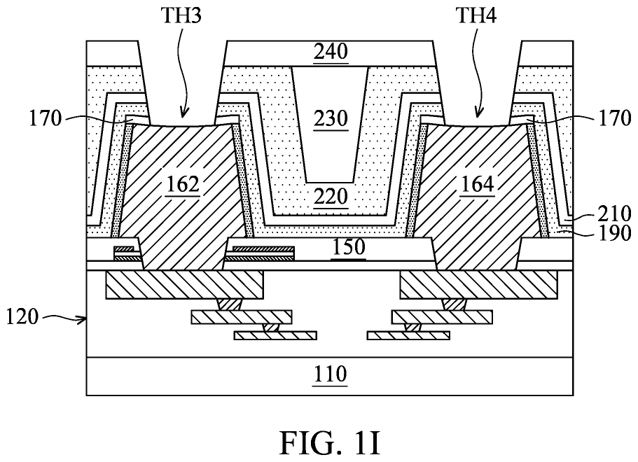

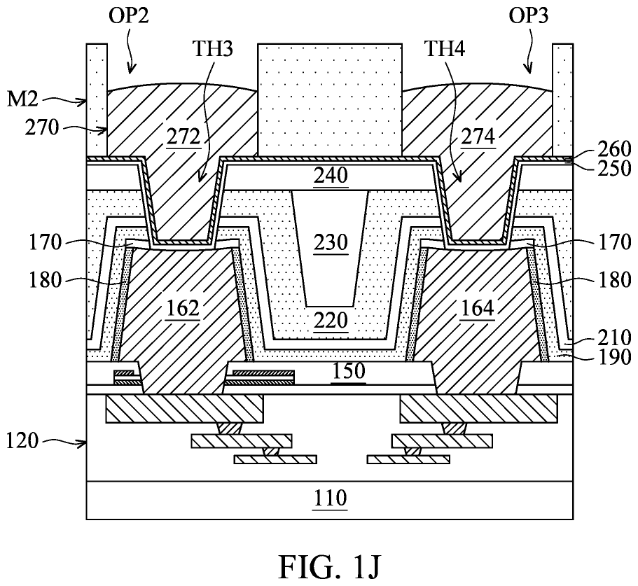

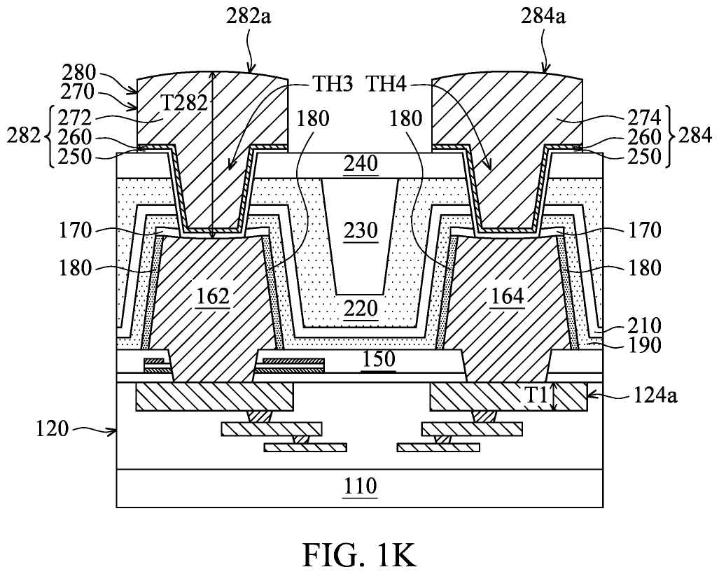

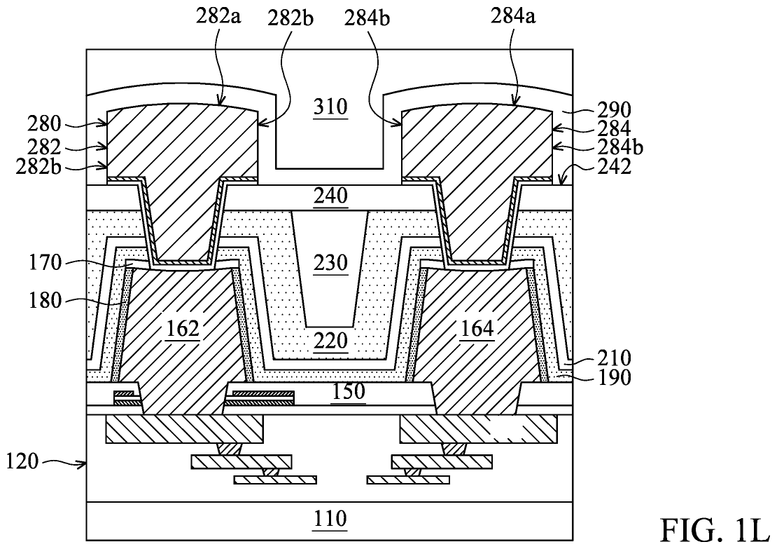

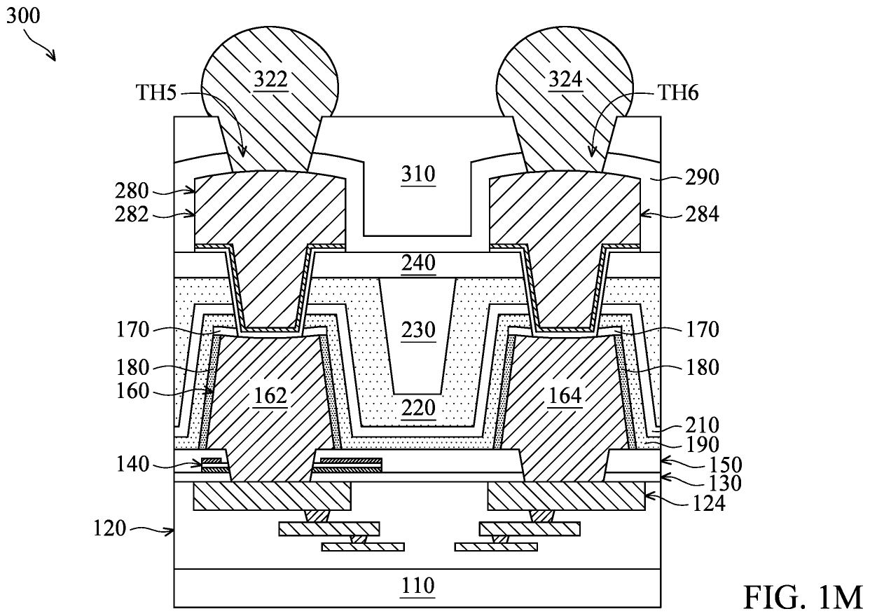

FIGS. 1A-1M are cross-sectional views of various stages of a process for forming a semiconductor device structure, in accordance with some embodiments. As shown in FIG. 1A, a substrate 110 is provided, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements (not shown). In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIG. 1A, an interconnect structure 120 is formed over the substrate 110, in accordance with some embodiments. The interconnect structure 120 includes a dielectric structure 122, wiring layers 124, and conductive vias 126, in accordance with some embodiments. The dielectric structure 122 is formed over a surface 112 of the substrate 110, in accordance with some embodiments.

The wiring layers 124 and the conductive vias 126 are formed in the dielectric structure 122, in accordance with some embodiments. The conductive vias 126 are electrically connected between different wiring layers 124 and between the wiring layer 124 and the aforementioned device elements, in accordance with some embodiments.

For the sake of simplicity, FIG. 1A only shows three wiring layers 124a, 124b, and 124c of the wiring layers 124, in accordance with some embodiments. The wiring layer 124a is a top-most wiring layer of the interconnect structure 120, in accordance with some embodiments.

The thickness T1 of the wiring layer 124a is greater than the thickness T2 of the wiring layer 124b, in accordance with some embodiments. The thickness T2 of the wiring layer 124b is greater than the thickness T3 of the wiring layer 124c, in accordance with some embodiments.

For the sake of simplicity, FIG. 1A only shows two conductive vias 126a and 126b of the conductive vias 126, in accordance with some embodiments. The width W126a of the conductive via 126a is greater than the width W126b of the conductive via 126b, in accordance with some embodiments.

The dielectric structure 122 is made of an oxide-containing material (e.g. silicon oxide or undoped silicate glass) or another suitable insulating material, in accordance with some embodiments. The wiring layers 124 and the conductive vias 126 are made of conductive materials such as metal (e.g., aluminum, copper, gold, silver, tungsten or the like) or alloys thereof, in accordance with some embodiments.

As shown in FIG. 1A, a passivation layer 130 is formed over the interconnect structure 120, in accordance with some embodiments. The passivation layer 130 is made of a dielectric material, such as silicon nitride, silicon oxynitride, silicon oxide, or undoped silicate glass (USG), in accordance with some embodiments. The passivation layer 130 is formed using a deposition process (e.g., a chemical vapor deposition process or a physical vapor deposition process), in accordance with some embodiments.

As shown in FIG. 1A, a metal-insulator-metal (MIM) capacitor 140 is formed over the passivation layer 130, in accordance with some embodiments. The MIM capacitor 140 includes a bottom metal layer 142, an insulating layer 144, and a top metal layer 146, in accordance with some embodiments. The insulating layer 144 is sandwiched between the bottom metal layer 142 and the top metal layer 146, in accordance with some embodiments.

The bottom metal layer 142 and the top metal layer 146 are made of titanium (Ti), titanium nitride (TiN), tantalum (Ta), tantalum nitride (TaN), copper (Cu), copper alloy, aluminum (Al), aluminum (Al) alloy, copper aluminum alloy (AlCu), tungsten (W), or tungsten (W) alloy, in accordance with some embodiments. The bottom metal layer 142 and the top metal layer 146 are formed by a procedure including depositing, photolithography, and etching processes.

The deposition processes include chemical vapor deposition (CVD), physical vapor deposition (PVD), atomic layer deposition (ALD), or applicable methods. The photolithography processes include photoresist coating (e.g., spin-on coating), soft baking, mask aligning, exposure, post-exposure baking, developing the photoresist, rinsing, and drying (e.g., hard baking), in accordance with some embodiments. The etching processes include dry etching, wet etching, and/or other etching methods.

The insulating layer 144 is made of dielectric materials, such as silicon oxide, silicon nitride or silicon glass. In some embodiments, the insulating layer 144 is formed by.

As shown in FIG. 1A, a passivation layer 150 is formed over the passivation layer 130 and the MIM capacitor 140, in accordance with some embodiments. The passivation layer 150 is made of a dielectric material, such as silicon nitride, silicon oxynitride, silicon oxide, or undoped silicate glass (USG), in accordance with some embodiments. The passivation layer 150 is formed using a deposition process (e.g., a chemical vapor deposition process or a physical vapor deposition process), in accordance with some embodiments.

As shown in FIG. 1A, portions of the passivation layers 130 and 150, the insulating layer 144, and the bottom metal layer 142 are removed to form through holes TH1 and TH2, in accordance with some embodiments. The through hole TH1 passes through the passivation layers 130 and 150, the insulating layer 144, and the bottom metal layer 142, in accordance with some embodiments. The through hole TH2 passes through the passivation layers 130 and 150, in accordance with some embodiments.

The through holes TH1 and TH2 expose portions of the wiring layer 124a and the bottom metal layer 142, in accordance with some embodiments. The removal process includes a photolithography process and an etching process, such as a dry etching process, in accordance with some embodiments.

As shown in FIG. 1A, a conductive layer 160a is formed over the passivation layer 150 and in the through holes TH1 and TH2, in accordance with some embodiments. The conductive layer 160a is connected to the wiring layer 124a and the bottom metal layer 142, in accordance with some embodiments. The top metal layer 146 has an opening 146a, and the conductive layer 160a passes through the opening 146a, in accordance with some embodiments.

The conductive layer 160a has recesses R1 and R2 over the through holes TH1 and TH2 respectively, in accordance with some embodiments. The conductive layer 160a has a thickness T160a ranging from about 20 KÅ to about 60 KÅ, in accordance with some embodiments.

The conductive layer 160a is made of a conductive material, such as metal (e.g., aluminum) or alloys (e.g., aluminum-copper alloy) thereof, in accordance with some embodiments. The conductive layer 160a is formed using a deposition process such as a physical vapor deposition (PVD) process or a chemical vapor deposition (CVD) process, in accordance with some embodiments.

As shown in FIG. 1A, a mask layer 170 is formed over a top surface 160a1 of the conductive layer 160a, in accordance with some embodiments. The mask layer 170 conformally covers the conductive layer 160a, in accordance with some embodiments. The mask layer 170 is partially in the recesses R1 and R2 of the conductive layer 160a, in accordance with some embodiments.

The mask layer 170 is made of a dielectric material, such as nitrides (e.g., silicon oxynitride), in accordance with some embodiments. The mask layer 170 is formed using a deposition process such as a chemical vapor deposition (CVD) process or a physical vapor deposition (PVD) process, in accordance with some embodiments.

As shown in FIG. 1A, a mask layer M1 is formed over the mask layer 170, in accordance with some embodiments. The mask layer M1 has openings OP1, in accordance with some embodiments. The openings OP1 expose portions of the mask layer 170, in accordance with some embodiments. The mask layer M1 is made of a polymer material such as a photoresist material, in accordance with some embodiments.

As shown in FIG. 1B, portions of the mask layer 170 are removed through the openings OP1 of the mask layer M1, in accordance with some embodiments. The removal process forms openings 172 in the mask layer 170, in accordance with some embodiments. The removal process includes an etching process such as a dry etching process, in accordance with some embodiments. The openings 172 expose portions of the conductive layer 160a, in accordance with some embodiments.

As shown in FIG. 1C, portions of the conductive layer 160a are removed through the openings OP1 of the mask layer M1 and the openings 172 of the mask layer 170, in accordance with some embodiments. After the removal process, the remaining conductive layer 160a forms a redistribution layer (RDL) 160, in accordance with some embodiments.

The redistribution layer 160 includes conductive pads 162 and 164 and conductive lines (not shown), in accordance with some embodiments. The conductive pads 162 and 164 are spaced apart from each other, in accordance with some embodiments. The conductive lines are connected to the conductive pads 162 and 164, in accordance with some embodiments.

The conductive pads 162 and 164 are electrically and physically connected to the wiring layer 124a exposed by the through holes TH1 and TH2, in accordance with some embodiments. The thickness T162 or T164 of the conductive pad 162 or 164 is greater than the thickness T1 of the wiring layer 124a, in accordance with some embodiments. The mask layer 170 covers top surfaces 162a and 164a of the conductive pads 162 and 164, in accordance with some embodiments.

The conductive pad 162 is electrically connected to the bottom metal layer 142 of the MIM capacitor 140, in accordance with some embodiments. The top metal layer 146 of the MIM capacitor 140 is electrically connected to another conductive pad (not shown), in accordance with some embodiments. The insulating layer 144 electrically insulates the bottom metal layer 142 from the top metal layer 146, in accordance with some embodiments.

The conductive pads 162 and 164 are made of a conductive material, such as metal (e.g., aluminum, copper, gold, silver, tungsten, or the like) or alloys thereof, in accordance with some embodiments.

As shown in FIG. 1D, the mask layer M1 is removed, in accordance with some embodiments. The removal process includes an etching process such as a dry etching process, in accordance with some embodiments. The mask layer 170 remains over the top surfaces 162a and 164a of the conductive pads 162 and 164, in accordance with some embodiments. The mask layer 170 is used as an etch stop layer in subsequent processes, in accordance with some embodiments.

As shown in FIGS. 1D and 1E, an oxidation process is performed over the sidewall portions 162b and 164b of the conductive pads 162 and 164, in accordance with some embodiments. The sidewall portions 162b and 164b are oxidized to form a metal oxide layer 180 over sidewalls 162s and 164s of the conductive pads 162 and 164, in accordance with some embodiments. The metal oxide layer 180 is used as an adhesive layer, in accordance with some embodiments.

The metal oxide layer 180 conformally covers the sidewalls 162s and 164s, in accordance with some embodiments. The metal oxide layer 180 is in direct contact with the conductive pads 162 and 164, in accordance with some embodiments. The metal oxide layer 180 and the conductive pads 162 and 164 include the same metal element, in accordance with some embodiments.

The metal element includes, for example, aluminum. The metal oxide layer 180 is made of aluminum oxide or another suitable material, in accordance with some embodiments. The metal oxide layer 180 has a thickness T180 ranging from about 0.1 KA to about 0.4 KÅ, in accordance with some embodiments.

The mask layer 170 covers the metal oxide layer 180, in accordance with some embodiments. The metal oxide layer 180 is in direct contact with the mask layer 170, in accordance with some embodiments. The mask layer 170 has a thickness T170 ranging from about 0.05 KÅ to about 0.15 KÅ, in accordance with some embodiments. The oxidation process uses a process gas including N₂O and/or O₂, in accordance with some embodiments. The process temperature of the oxidation process ranges from about 100° C. to about 300° C., in accordance with some embodiments.

As shown in FIG. 1F, a semiconductor oxide layer 190 is formed over the mask layer 170 and the metal oxide layer 180, in accordance with some embodiments. The semiconductor oxide layer 190 is used as an adhesive layer, in accordance with some embodiments. The semiconductor oxide layer 190 is used as a stress release layer, in accordance with some embodiments.

The semiconductor oxide layer 190 conformally covers the mask layer 170 and the metal oxide layer 180, in accordance with some embodiments. The semiconductor oxide layer 190 is in direct contact with the mask layer 170 and the metal oxide layer 180, in accordance with some embodiments.

The semiconductor oxide layer 190 has a thickness T190 ranging from about 0.5 KÅ to about 1.5 KÅ, in accordance with some embodiments. The semiconductor oxide layer 190 is made of undoped silicate glass, silicon oxide, or the like, in accordance with some embodiments.

The semiconductor oxide layer 190 is formed using a deposition process such as a chemical vapor deposition (CVD) process or a physical vapor deposition (PVD) process, in accordance with some embodiments. In some embodiments, the step of FIG. 1E may be omitted, and the metal oxide layer 180 is formed during forming the semiconductor oxide layer 190.

As shown in FIG. 1F, a nitride layer 210 is formed over the semiconductor oxide layer 190, in accordance with some embodiments. The nitride layer 210 is used as an etch stop layer in subsequent processes, in accordance with some embodiments. The nitride layer 210 has a thickness T210 ranging from about 0.5 KÅ to about 1 KÅ, in accordance with some embodiments.

The nitride layer 210 is made of nitrides such as silicon nitride or the like, in accordance with some embodiments. The nitride layer 210 is formed using a deposition process such as a chemical vapor deposition (CVD) process or a physical vapor deposition (PVD) process, in accordance with some embodiments.

As shown in FIG. 1G, an oxide layer 220 is formed over the nitride layer 210, in accordance with some embodiments. The oxide layer 220 has a thickness T220 ranging from about 7 KÅ to about 11 KÅ, in accordance with some embodiments. The oxide layer 220 is made of oxides such as silicon oxide or the like, in accordance with some embodiments.

The oxide layer 220 is formed using a deposition process such as a chemical vapor deposition (CVD) process, in accordance with some embodiments. The chemical vapor deposition process includes a high density plasma CVD (HDP-CVD) process, in accordance with some embodiments.

As shown in FIG. 1G, a oxide layer 230 is formed over the oxide layer 220 and in the recess 222 of the oxide layer 220, in accordance with some embodiments. The oxide layer 230 is in direct contact with the oxide layer 220, in accordance with some embodiments. The oxide layer 230 is made of undoped silicate glass, silicon oxide, or the like, in accordance with some embodiments. The oxide layer 230 is formed using a deposition process such as a chemical vapor deposition (CVD) process or a physical vapor deposition (PVD) process, in accordance with some embodiments.

As shown in FIG. 1H, top portions of the oxide layer 230 outside of the recess 222 of the oxide layer 220 are removed, in accordance with some embodiments. The removal process includes a planarization process such as a chemical mechanical polishing process, in accordance with some embodiments.

As shown in FIG. 1H, a nitride layer 240 is formed over the oxide layers 220 and 230, in accordance with some embodiments. The nitride layer 240 is used to prevent moisture from being absorbed by the components underneath, in accordance with some embodiments.

The nitride layer 240 has a thickness T240 ranging from about 5 KÅ to about 9 KÅ, in accordance with some embodiments. The nitride layer 240 is made of nitrides such as silicon nitride or the like, in accordance with some embodiments. The nitride layer 240 is formed using a deposition process such as a chemical vapor deposition (CVD) process or a physical vapor deposition (PVD) process, in accordance with some embodiments.

As shown in FIG. 1I, portions of the mask layer 170, the semiconductor oxide layer 190, the nitride layer 210, the oxide layer 220, and the nitride layer 240 are removed to form through holes TH3 and TH4 passing through the mask layer 170, the semiconductor oxide layer 190, the nitride layer 210, the oxide layer 220, and the nitride layer 240, in accordance with some embodiments.

The through hole TH3 exposes a portion of the conductive pad 162, in accordance with some embodiments. The through hole TH4 exposes a portion of the conductive pad 164, in accordance with some embodiments. The removal process includes an etching process such as a dry etching process, in accordance with some embodiments.

As shown in FIG. 1J, a barrier layer 250 is formed over the nitride layer 240 and in the through holes TH3 and TH4, in accordance with some embodiments. The barrier layer 250 is made of nitrides such as tantalum nitride (TaN), in accordance with some embodiments. In some embodiments, the barrier layer 250 is a multilayer structure including a tantalum layer and a tantalum nitride layer over the tantalum layer.

The barrier layer 250 is formed using a deposition process, such as a physical vapor deposition (PVD) process, a chemical vapor deposition (CVD) process, or an atomic layer deposition (ALD) process, in accordance with some embodiments.

As shown in FIG. 1J, a seed layer 260 is conformally formed over the barrier layer 250, in accordance with some embodiments. In some embodiments, the barrier layer 250 is not formed. The seed layer 260 is made of a conductive material, such as metal (e.g., copper, aluminum, gold, silver, tungsten, titanium, cobalt, or ruthenium) or alloys thereof, in accordance with some embodiments.

The seed layer 260 is formed using a deposition process, such as a physical vapor deposition (PVD) process, a chemical vapor deposition (CVD) process, or an atomic layer deposition (ALD) process, in accordance with some embodiments.

As shown in FIG. 1J, a mask layer M2 is formed over the seed layer 260, in accordance with some embodiments. The mask layer M2 has openings OP2 and OP3 exposing portions of the seed layer 260, in accordance with some embodiments. The openings OP2 and OP3 expose portions of the seed layer 260 in the through holes TH3 and TH4 and portions of the seed layer 260 over the conductive pads 162 and 164, in accordance with some embodiments. The mask layer M2 is made of a polymer material, such as a photoresist material, in accordance with some embodiments.

After the mask layer M2 is formed, a descum process is performed over the seed layer 260 exposed by the openings OP2 and OP3 to remove the residues over the seed layer 260, in accordance with some embodiments. The de scum process includes an etching process such as a plasma etching process, in accordance with some embodiments.

As shown in FIG. 1J, a conductive layer 270 is formed over the seed layer 260 exposed by the openings OP2 and OP3 of the mask layer M2, in accordance with some embodiments. The conductive layer 270 includes portions 272 and 274, in accordance with some embodiments. The portion 272 is in the opening OP2 and the through hole TH3, in accordance with some embodiments. The portion 274 is in the opening OP3 and the through hole TH4, in accordance with some embodiments.

The conductive layer 270 is made of a conductive material, such as metal (e.g., copper) or alloys thereof, in accordance with some embodiments. The conductive layer 270 is formed by a plating process, such as an electroplating process, in accordance with some embodiments.

As shown in FIG. 1K, the mask layer M2 is removed, in accordance with some embodiments. As shown in FIG. 1K, the seed layer 260 originally under the mask layer M2 is removed, in accordance with some embodiments. The removal process includes an etching process such as a wet etching process or a dry etching process, in accordance with some embodiments.

The barrier layer 250, which is not covered by the conductive layer 270, is removed, in accordance with some embodiments. The removal process includes an etching process such as a dry etching process or a wet etching process, in accordance with some embodiments. In this step, a redistribution layer (RDL) 280 is formed, in accordance with some embodiments.

As shown in FIG. 1K, the portion 272 of the conductive layer 270, the seed layer 260 thereunder, and the barrier layer 250 thereunder together form a conductive pad 282, in accordance with some embodiments. The portion 274 of the conductive layer 270, the seed layer 260 thereunder, and the barrier layer 250 thereunder together form a conductive pad 284, in accordance with some embodiments.

The redistribution layer 280 includes the conductive pads 282 and 284 and conductive lines (not shown), in accordance with some embodiments. The conductive lines are connected to the conductive pads 282 and 284, in accordance with some embodiments. The conductive pad 282 is thicker than the wiring layer 124a, in accordance with some embodiments. That is, a thickness T282 of the conductive pad 282 is greater than the thickness T1 of the wiring layer 124a, in accordance with some embodiments.

The conductive pads 282 and 284 pass through the nitride layer 240, the oxide layer 220, the nitride layer 210, the semiconductor oxide layer 190, and the mask layer 170, in accordance with some embodiments. The conductive pad 282 is directly connected to the conductive pad 162, in accordance with some embodiments. The conductive pad 284 is directly connected to the conductive pad 164, in accordance with some embodiments. The conductive pads 162 and 164 and the conductive pads 282 and 284 are made of different materials, in accordance with some embodiments.

The conductive pad 282 has a top surface 282a, in accordance with some embodiments. Since the electroplating process for forming the conductive layer 270 of the conductive pad 282 has good hole-filling ability, the top surface 282a does not has small recesses over the through hole TH3, in accordance with some embodiments. In some embodiments, the top surface 282a is a convex top surface (or a dome surface). Similarly, the top surface 284a of the conductive pad 284 is a convex top surface (or a dome surface), in accordance with some embodiments.

As shown in FIG. 1L, a passivation layer 290 is conformally formed over the nitride layer 240 and the conductive pads 282 and 284, in accordance with some embodiments. The passivation layer 290 conformally covers the top surface 282a and sidewalls 282b of the conductive pad 282, a top surface 284a and sidewalls 284b of each conductive pad 284, and the top surface 242 of the nitride layer 240, in accordance with some embodiments.

The passivation layer 290 is made of a dielectric material, such as nitrides (e.g., silicon nitride or silicon oxynitride), in accordance with some embodiments. The passivation layer 290 is formed using a deposition process (e.g., a chemical vapor deposition process, a physical vapor deposition process, or an atomic layer deposition process), in accordance with some embodiments.

As shown in FIG. 1L, a protective layer 310 is formed over the passivation layer 290, in accordance with some embodiments. The protective layer 310 is made of an insulating material such as a polymer material (e.g., polyimide), in accordance with some embodiments. The protective layer 310 is formed using a coating process such as a spin-on coating process, in accordance with some embodiments.

As shown in FIG. 1M, portions of the passivation layer 290 and the protective layer 310 are removed to form through holes TH5 and TH6, in accordance with some embodiments. The through hole TH5 passes through the passivation layer 290 and the protective layer 310 and exposes a portion of the conductive pad 282, in accordance with some embodiments. The through hole TH6 passes through the passivation layer 290 and the protective layer 310 and exposes a portion of the conductive pad 284, in accordance with some embodiments.

As shown in FIG. 1M, a conductive bump 322 is formed in the through hole TH5 and over the conductive pad 282, in accordance with some embodiments. As shown in FIG. 1M, a conductive bump 324 is formed in the through hole TH6 and over the conductive pad 284, in accordance with some embodiments. The conductive bumps 322 and 324 are made of a conductive material, such as metal (e.g., tin or the like) or alloys thereof, in accordance with some embodiments.

The conductive bumps 322 and 324 are formed using a plating process, such as an electroplating process, in accordance with some embodiments. In some other embodiments, the conductive bumps 322 and 324 are formed using a ball mount process. In this step, a semiconductor device structure 300 is substantially formed, in accordance with some embodiments.

Since the metal oxide layer 180 has good adhesion to the conductive pads 162 and 164 and the semiconductor oxide layer 190, the formation of the metal oxide layer 180 prevents the delamination of the semiconductor oxide layer 190 from the conductive pads 162 and 164, in accordance with some embodiments.

Since the semiconductor oxide layer 190 has good adhesion to the metal oxide layer 180 and the nitride layer 210, the formation of the semiconductor oxide layer 190 prevents the delamination of the nitride layer 210 from the conductive pads 162 and 164, in accordance with some embodiments. Therefore, the reliability of the semiconductor device structure 300 is improved, in accordance with some embodiments.

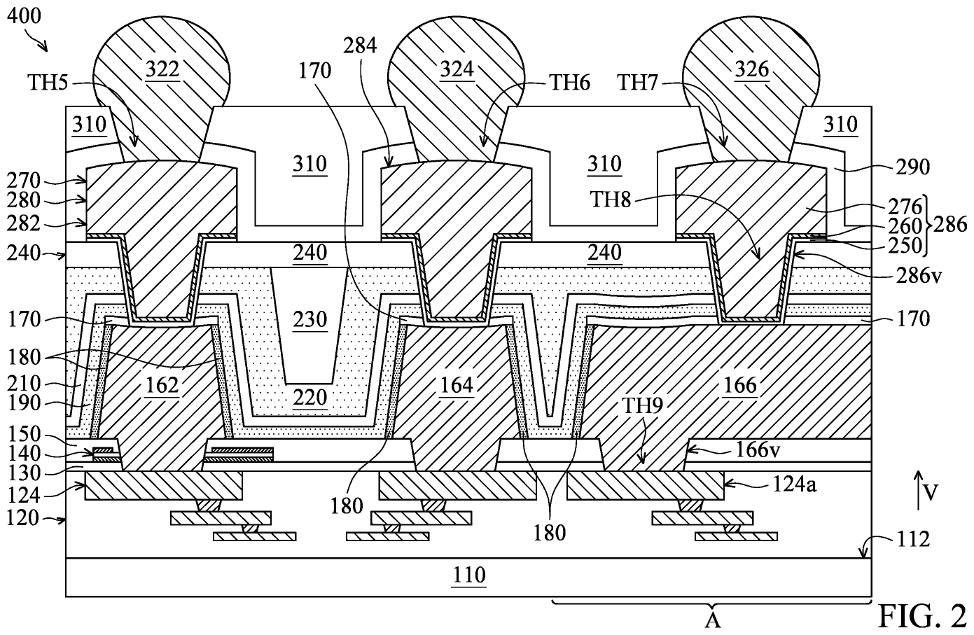

FIG. 2 is a cross-sectional view of a semiconductor device structure 400, in accordance with some embodiments. As shown in FIG. 2, the semiconductor device structure 400 is similar to the semiconductor device structure 300 of FIG. 1M, except that the semiconductor device structure 400 further has the portion A, in accordance with some embodiments.

Specifically, the semiconductor device structure 400 further has a conductive pad 166, a conductive pad 286, and a conductive bump 326, in accordance with some embodiments. The conductive pad 166 is over the passivation layer 150, in accordance with some embodiments. The conductive pad 166 is partially in a through hole TH9 passing through the passivation layers 130 and 150, in accordance with some embodiments. The conductive pad 166 is connected to the wiring layer 124a, in accordance with some embodiments.

The conductive pad 286 includes a portion 276 of the conductive layer 270, the seed layer 260 thereunder, and the barrier layer 250 thereunder, in accordance with some embodiments. The conductive pad 286 is over the nitride layer 240 and in a through hole TH8 passing through the mask layer 170, the semiconductor oxide layer 190, the nitride layer 210, the oxide layer 220, and the nitride layer 240, in accordance with some embodiments. The conductive pad 286 is electrically and physically connected to the conductive pad 166, in accordance with some embodiments.

The through holes TH8 and TH9 are misaligned in a direction V perpendicular to the top surface 112 of the substrate 110, in accordance with some embodiments. That is, the portion 286v of the conductive pad 286 in the through hole TH8 and the portion 166v of the conductive pad 166 in the through hole TH9 are misaligned in the direction V, in accordance with some embodiments.

The conductive bump 326 is over the protective layer 310 and in a through hole TH7 passing through the protective layer 310 and the passivation layer 290, in accordance with some embodiments. The conductive bump 326 is electrically and physically connected to the conductive pad 286, in accordance with some embodiments. The materials of the conductive pad 166, the conductive pad 286, and the conductive bump 326 are similar to or the same as that of the conductive pad 162, the conductive pad 282, and the conductive bump 322, in accordance with some embodiments.

Processes and materials for forming the semiconductor device structure 400 may be similar to, or the same as, those for forming the semiconductor device structure 300 described above. Elements designated by the same or similar reference numbers as those in FIGS. 1A to 2 have the same or similar structures and the materials. Therefore, the detailed descriptions thereof will not be repeated herein.

In accordance with some embodiments, semiconductor device structures and methods for forming the same are provided. The methods (for forming the semiconductor device structure) sequentially form a metal oxide layer, a semiconductor oxide layer, and a nitride layer over sidewalls of a conductive pad. Since the metal oxide layer has good adhesion to the conductive pad and the semiconductor oxide layer, the formation of the metal oxide layer prevents the delamination of the semiconductor oxide layer from the conductive pad. Since the semiconductor oxide layer has good adhesion to the metal oxide layer and the nitride layer, the formation of the semiconductor oxide layer prevents the delamination of the nitride layer from the conductive pad. Therefore, the reliability of the semiconductor device structure is improved.

In accordance with some embodiments, a method for forming a semiconductor device structure is provided. The method includes forming an interconnect structure over a substrate. The method includes forming a first conductive pad and a mask layer over the interconnect structure. The mask layer covers a top surface of the first conductive pad. The method includes forming a metal oxide layer over a sidewall of the first conductive pad. The method includes forming a second conductive pad over the first conductive pad and passing through the mask layer. The first conductive pad and the second conductive pad are made of different materials.

In accordance with some embodiments, a method for forming a semiconductor device structure is provided. The method includes forming an interconnect structure over a substrate. The method includes forming a first conductive pad and a mask layer over the interconnect structure. The mask layer covers a top surface of the first conductive pad. The method includes oxidizing a sidewall portion of the first conductive pad to form a metal oxide layer over the first conductive pad. The method includes forming a semiconductor oxide layer over the mask layer and the metal oxide layer.

In accordance with some embodiments, a semiconductor device structure is provided. The semiconductor device structure includes a substrate. The semiconductor device structure includes an interconnect structure over the substrate. The semiconductor device structure includes a first conductive pad over the interconnect structure. The semiconductor device structure includes a mask layer over a top surface of the first conductive pad. The semiconductor device structure includes a metal oxide layer over a sidewall of the first conductive pad. The semiconductor device structure includes a second conductive pad over and passing through the mask layer. The first conductive pad and the second conductive pad are made of different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming an interconnect structure over a substrate;
forming a first conductive pad and a mask layer over the interconnect structure, wherein the mask layer covers a top surface of the first conductive pad;
forming a metal oxide layer over a sidewall of the first conductive pad; and
forming a second conductive pad over the first conductive pad and passing through the mask layer, wherein the first conductive pad and the second conductive pad are made of different materials.

2. The method for forming the semiconductor device structure as claimed in claim 1, wherein the mask layer covers the metal oxide layer.

3. The method for forming the semiconductor device structure as claimed in claim 1, wherein the metal oxide layer is in direct contact with the first conductive pad.

4. The method for forming the semiconductor device structure as claimed in claim 3, wherein the metal oxide layer is in direct contact with the mask layer.

5. The method for forming the semiconductor device structure as claimed in claim 1, wherein the metal oxide layer conformally covers a sidewall of the first conductive pad.

6. The method for forming the semiconductor device structure as claimed in claim 1, wherein the metal oxide layer and the first conductive pad comprises a same metal element.

7. The method for forming the semiconductor device structure as claimed in claim 6, wherein the metal element comprises aluminum.

8. The method for forming the semiconductor device structure as claimed in claim 1, further comprising:
forming a conductive bump over the second conductive pad.

9. The method for forming the semiconductor device structure as claimed in claim 1, further comprising:
forming a semiconductor oxide layer over the mask layer and the metal oxide layer.

10. The method for forming the semiconductor device structure as claimed in claim 9, wherein the semiconductor oxide layer is in direct contact with the mask layer and the metal oxide layer.

11. A method for forming a semiconductor device structure, comprising:
forming an interconnect structure over a substrate;
forming a first conductive pad and a mask layer over the interconnect structure, wherein the mask layer covers a top surface of the first conductive pad;
oxidizing a sidewall portion of the first conductive pad to form a metal oxide layer over the first conductive pad; and
forming a semiconductor oxide layer over the mask layer and the metal oxide layer.

12. The method for forming the semiconductor device structure as claimed in claim 11, wherein the semiconductor oxide layer conformally covers the mask layer and the metal oxide layer.

13. The method for forming the semiconductor device structure as claimed in claim 12, further comprising:
forming a nitride layer over the semiconductor oxide layer.

14. The method for forming the semiconductor device structure as claimed in claim 13, further comprising:
forming an oxide layer over the nitride layer.

15. The method for forming the semiconductor device structure as claimed in claim 14, further comprising:
forming a second conductive pad over the oxide layer, wherein the second conductive pad passes through the oxide layer, the nitride layer, the semiconductor oxide layer, and the mask layer and is connected to the first conductive pad.

16. A semiconductor device structure, comprising:
a substrate;
an interconnect structure over the substrate;
a first conductive pad over the interconnect structure;
a mask layer over a top surface of the first conductive pad;
a metal oxide layer over a sidewall of the first conductive pad; and
a second conductive pad over and passing through the mask layer, wherein the first conductive pad and the second conductive pad are made of different materials.

17. The semiconductor device structure as claimed in claim 16, wherein the mask layer covers the metal oxide layer.

18. The semiconductor device structure as claimed in claim 16, wherein the metal oxide layer and the first conductive pad comprises a same metal element.

19. The semiconductor device structure as claimed in claim 18, wherein the metal element comprises aluminum.

20. The semiconductor device structure as claimed in claim 16, further comprising:
a semiconductor oxide layer conformally covering the mask layer and the metal oxide layer.
